(19) United States
(12) Patent Application Publication
(10) Pub. No.: US 2026/0190584 A1
(43) Pub. Date: Jul. 2, 2026

(54) DISPLAY DEVICE

(71) Applicant: AUO Corporation, Hsinchu City (TW)

(72) Inventors: Min-Ching Tsai, Hsinchu City (TW); Tzu-Chin Huang, Hsinchu City (TW)

(73) Assignee: AUO Corporation, Hsinchu City (TW)

(21) Appl. No.: 19/260,638

(22) Filed: Jul. 7, 2025

(30) Foreign Application Priority Data
Dec. 26, 2024 (TW) 113151005

(51) Int. Cl. H10H 29/85; H10H 29/851

(52) U.S. Cl. CPC H10H 29/8517; H10H 29/8514

(57) ABSTRACT

A display device includes a pixel unit and a photoluminescent layer. The pixel unit includes a first sub-pixel and a second sub-pixel. The first sub-pixel includes a first light-emitting element and a first filter layer. The first filter layer is disposed above the first light-emitting element. The second sub-pixel includes a second light-emitting element and a second filter layer. The second filter layer is disposed above the second light-emitting element. A portion of the photoluminescent layer is located between the first light-emitting element and the first filter layer and laterally covers a sidewall of the first light-emitting element. Another portion of the photoluminescent layer is located between the second light-emitting element and the second filter layer and laterally covers a sidewall of the second light-emitting element. The first sub-pixel and the second sub-pixels are configured to emit light of different colors.

### CROSS-REFERENCE TO RELATED APPLICATION

This application claims the priority benefit of Taiwan application Ser. No. 113151005 filed on Dec. 26, 2024. The entirety of the above-mentioned patent application is hereby incorporated by reference herein and made a part of this specification.

### BACKGROUND

### Technical Field

The disclosure is related to a display device.

### Related Art

The micro light-emitting diode display device uses micro light-emitting diodes as light-emitting elements in pixels. As the size of light-emitting elements gradually decreases, the pixels per inch (PPI) increases, thereby enabling the display device to achieve higher resolution display screens. However, as the size of light-emitting elements decreases, several issues arise, such as reduced external quantum efficiency of the light-emitting elements, which further affects the display quality of the display device. In addition, as the pixel size decreases, different light-emitting elements in the same pixel are prone to cross talk, leading to color shift problems.

### SUMMARY

The disclosure provides a display device, which has better light concentration efficiency and reduced color shift in the left/right viewing angle directions.

The display device of the disclosure includes a pixel unit and a photoluminescent layer. The pixel unit includes a first sub-pixel and a second sub-pixel. The first sub-pixel includes a first light-emitting element and a first filter layer. The first filter layer is disposed above the first light-emitting element. The second sub-pixel includes a second light-emitting element and a second filter layer. The second filter layer is disposed above the second light-emitting element. A portion of the photoluminescent layer is located between the first light-emitting element and the first filter layer and laterally covers a sidewall of the first light-emitting element. Another portion of the photoluminescent layer is located between the second light-emitting element and the second filter layer and laterally covers a sidewall of the second light-emitting element. The first sub-pixel and the second sub-pixels are configured to emit light of different colors.

Based on the above, in the display device of the disclosure, a portion of the photoluminescent layer is located between the first light-emitting element and the first filter layer and laterally covers the sidewall of the first light-emitting element, another portion of the photoluminescent layer is located between the second light-emitting element and the second filter layer and laterally covers the sidewall of the second light-emitting element, and the first sub-pixel and the second sub-pixel are configured to emit light of different colors. As such, the display device has better light concentration efficiency and energy-saving efficiency, as well as reduced color shift in the left/right viewing angle directions.

### BRIEF DESCRIPTION OF THE DRAWINGS

FIG. 1A is a top view schematic diagram of one of pixel units in a display device according to an embodiment of the disclosure.

FIG. 1B is a cross-sectional schematic diagram of one of the pixel units in the display device and a seam S between display panels according to an embodiment of the disclosure.

FIG. 1C is a relationship diagram between horizontal viewing angle and relative intensity according to an embodiment of the disclosure.

FIG. 1D is a relationship diagram between horizontal viewing angle and relative intensity according to an embodiment of the disclosure.

FIG. 1E is a relationship diagram between horizontal viewing angle and relative intensity according to an embodiment of the disclosure.

FIG. 2 is a cross-sectional schematic diagram of one of the pixel units and the seam S between the display panels according to another embodiment of the disclosure.

FIG. 3 is a cross-sectional schematic diagram of one of the pixel units and the seam S between the display panels according to another embodiment of the disclosure.

FIG. 4 is a cross-sectional schematic diagram of one of the pixel units and the seam S between the display panels according to another embodiment of the disclosure.

### DESCRIPTION OF THE EMBODIMENTS

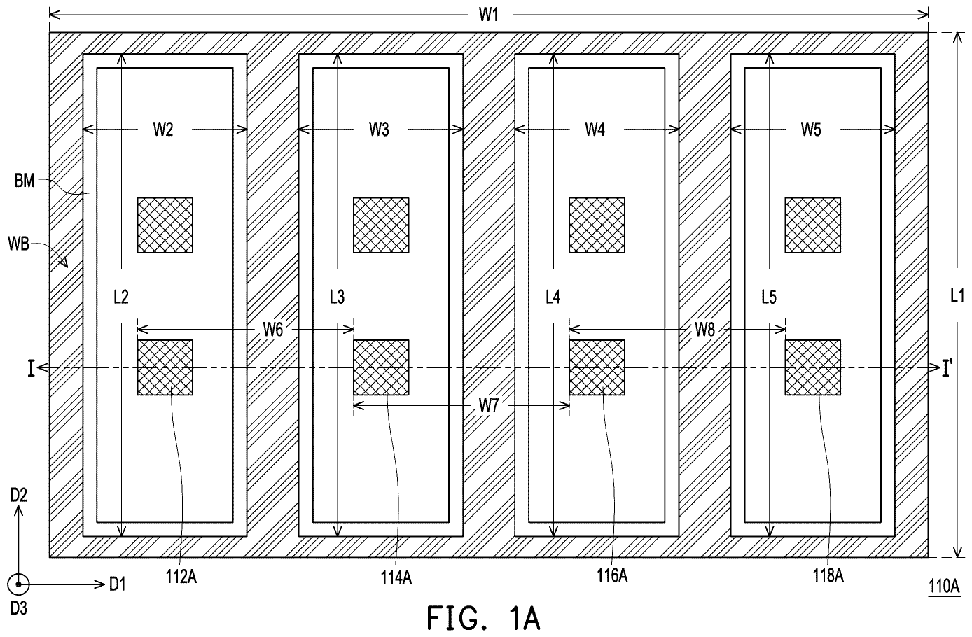

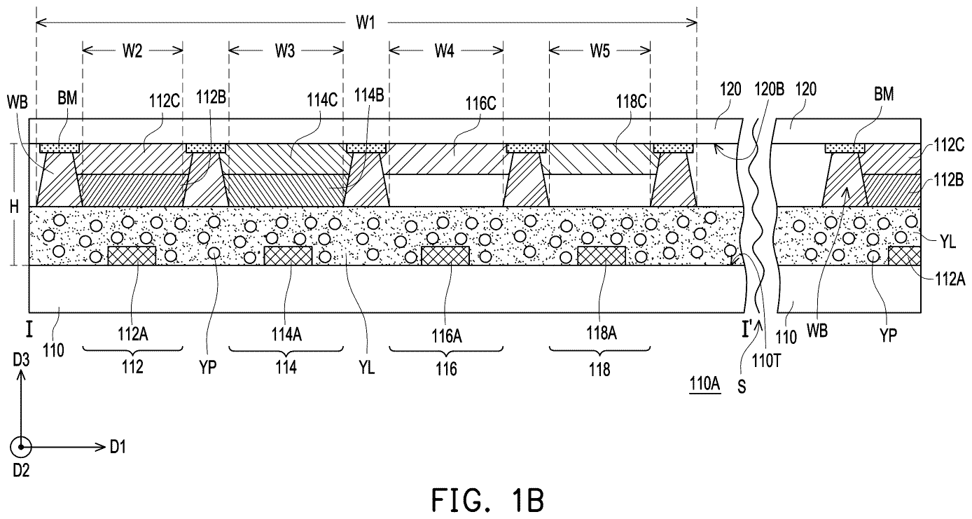

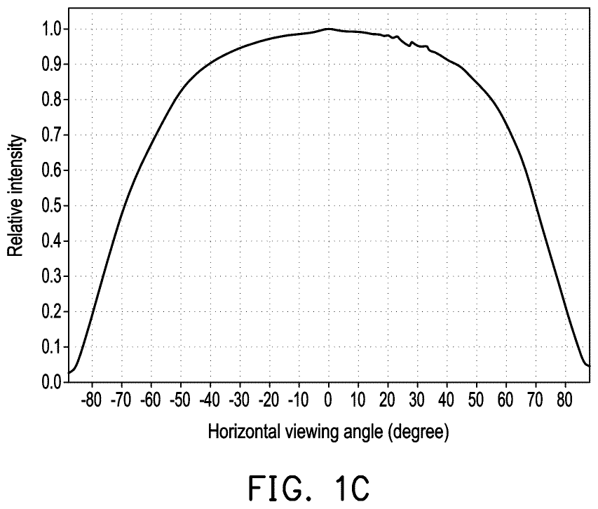

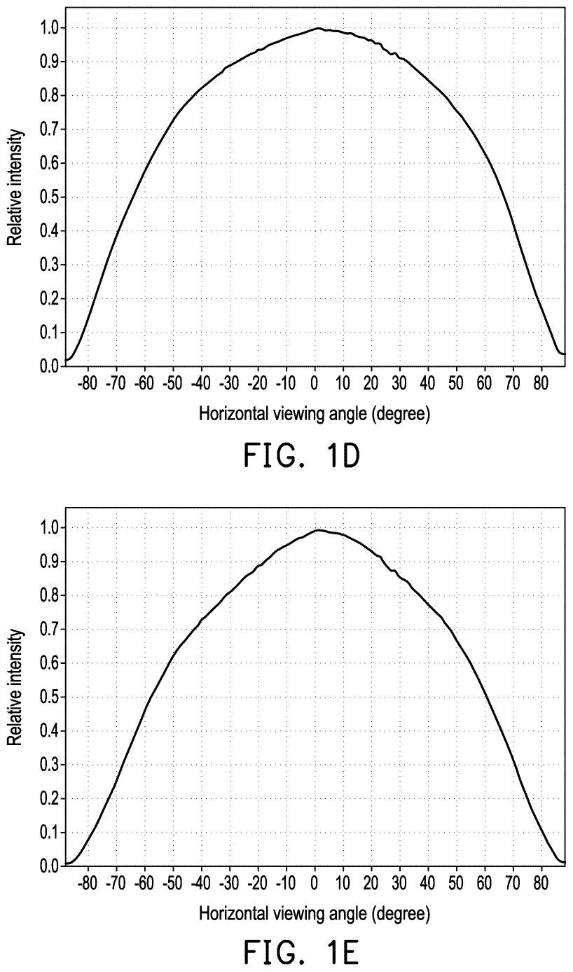

FIG. 1A is a top view schematic diagram of one of pixel units in a display device according to an embodiment of the disclosure. In some embodiments, the display device is a tiled display device including multiple display panels. FIG. 1B is a cross-sectional schematic diagram of one of the pixel units in the display device and a seam S between display panels according to an embodiment of the disclosure, in which FIG. 1B shows a cross-sectional schematic diagram along line a I-I′ in FIG. 1A. Please refer to FIG. 1A and FIG. 1B simultaneously. A display device includes a pixel unit 110A. The pixel unit 110A includes a first sub-pixel 112 and a second sub-pixel 114. The first sub-pixel 112 includes a first light-emitting element 112A and a first filter layer 112C. The first filter layer 112C is disposed above the first light-emitting element 112A. The second sub-pixel 114 includes a second light-emitting element 114A and a second filter layer 114C. The second filter layer 114C is disposed above the second light-emitting element 114A. The first light-emitting element 112A and the second light-emitting element 114A emit light of the same color (or referred to as light of a first color). For example, the first light-emitting element 112A and the second light-emitting element 114A are both blue light-emitting diodes, and the light of the first color is blue light.

The light-emitting element may include, for example, an organic light emitting diode (OLED) or a micro LED, but the disclosure is not limited thereto.

The display device further includes a photoluminescent layer YL. A portion of the photoluminescent layer YL is located between the first light-emitting element 112A and the first filter layer 112C, and another portion of the photoluminescent layer YL is located between the second light-emitting element 114A and the second filter layer 114C. The photoluminescent layer YL laterally covers a sidewall of the first light-emitting element 112A and a sidewall of the second light-emitting element 114A. The photoluminescent layer YL is adapted to convert the light of the first color emitted by the first light-emitting element 112A and the second light-emitting element 114A into light of a second color. For example, the photoluminescent layer YL absorbs at least a portion of the light of the first color emitted by the first light-emitting element 112A and the second light-emitting element 114A, and emits the light of the second color. For example, the light of the second color is yellow light.

Since the display device includes the photoluminescent layer YL, the brightness of the first sub-pixel 112 in the display device may be increased, for example, by 15.53 nit, and the brightness of the second sub-pixel 114 may be increased, for example, by 2.79 nit. At the same time, compared with conventional display devices, the display device has an energy-saving efficiency of up to 47%. In addition, a photosphere may be formed within the display device through the disposition of the photoluminescent layer YL, performing characteristic light compensation, further alleviating the visual issues of the seam S.

The first filter layer 112C is disposed above the photoluminescent layer YL and is adapted to filter the light of the second color into light of a third color. For example, the first filter layer 112C is a red filter layer, and yellow light is filtered into red light after passing through the red filter layer.

The first sub-pixel 112 further includes a first color conversion structure 112B. The first color conversion structure 112B is disposed above the first light-emitting element 112A, and is located between the photoluminescent layer YL and the first filter layer 112C. A portion of the photoluminescent layer YL is located between the first color conversion structure 112B and the first light-emitting element 112A.

In some embodiments, the photoluminescent layer YL includes photoluminescent particles and diffusion particles YP. The photoluminescent layer YL may be, for example, fluorescent material, phosphorescent material, or other suitable materials. The photoluminescent layer YL includes a base material (such as photoresist or other organic materials), with the photoluminescent particles and the diffusion particles YP dispersed in the base material.

In some embodiments, the weight percent concentration of the photoluminescent particles in the photoluminescent layer YL falls within the range of 40% to 60%, while the weight percent concentration of the diffusion particles YP falls within the range of 0.5% to 20%. In some embodiments, the particle size of the photoluminescent particles falls within the range of 0.1 micrometers to 5 micrometers, while the size of the diffusion particles YP falls within the range of 0.1 micrometers to 1 micrometer. The material of the diffusion particles YP may be titanium dioxide or other suitable materials.

In the present embodiment, the photoluminescent layer YL may absorb light emitted from the first light-emitting element 112A or the second light-emitting element 114A (wavelength range of, for example, approximately 425 nm to 495 nm) and emit light of other colors (wavelength range of, for example, approximately 425 nm to 750 nm). The first color conversion structure 112B may absorb light emitted from the photoluminescent layer YL and emit light converted to another color (wavelength range of, for example, approximately 620 nm to 750 nm). A second color conversion structure 114B may absorb light emitted from the photoluminescent layer YL and emit light of yet another color (wavelength range of, for example, approximately 495 nm to 570 nm), but the disclosure is not limited thereto.

The pixel unit 110A further includes a third sub-pixel 116. The third sub-pixel 116 includes a third light-emitting element 116A and a third filter layer 116C. The third light-emitting element 116A emits light of the same color (or referred to as light of the first color) as the first light-emitting element 112A and the second light-emitting element 114A. The third filter layer 116C is a blue filter layer. Still another portion of the photoluminescent layer YL is located between the third light-emitting element 116A and the third filter layer 116C. The photoluminescent layer YL laterally covers the sidewall of the third light-emitting element 116A. The light is emitted from the third light-emitting element 116A (wavelength range of, for example, approximately 425 nm to 495 nm), the photoluminescent layer YL may absorb the light emitted from the third light-emitting element 116A and then emit light of other colors (wavelength range of, for example, approximately 425 nm to 750 nm), and is filtered into blue by the third filter layer 116C.

The pixel unit 110A further includes a fourth sub-pixel 118. The fourth sub-pixel 118 includes a fourth light-emitting element 118A and a fourth filter layer 118C. The fourth light-emitting element 118A emits light of the same color (or referred to as light of the first color) as the first light-emitting element 112A, the second light-emitting element 114A, and the third light-emitting element 116A. The fourth filter layer 118C is disposed on the fourth light-emitting element 118A. The fourth filter layer 118C is a yellow filter layer. Yet another portion of the photoluminescent layer YL is located between the fourth light-emitting element 118A and the fourth filter layer 118C. The photoluminescent layer YL laterally covers the sidewall of the fourth light-emitting element 118A. The photoluminescent layer YL is adapted to absorb light emitted from the fourth light-emitting element 118A (wavelength range of, for example, approximately 425 nm to 495 nm) and emit light of other colors (wavelength range of, for example, approximately 425 nm to 750 nm), which is filtered into yellow by the fourth filter layer 118C.

The peak wavelength of the light emitted from the photoluminescent layer YL falls within the range of 540 nanometers to 580 nanometers, with a full width at half maximum falling within a range of less than 125 nanometers. The light emitted from the first color conversion structure 112B has a peak wavelength falling within the range of 614 nanometers to 625 nanometers, with a full width at half maximum falling within a range of less than 50 nanometers. The peak wavelength of the light emitted from the second color conversion structure 114B falls within the range of 515 nanometers to 525 nanometers, with a full width at half maximum falling within a range of less than 50 nanometers.

The display device further includes a first substrate 110 and a second substrate 120. The first substrate 110 and the second substrate 120 may be light-transmitting substrates. In a third direction D3 (Z-axis direction), the second substrate 120 is disposed on the first substrate 110. The first substrate 110 is overlapped with the second substrate 120. The first light-emitting element 112A and the second light-emitting element 114A are disposed on the first substrate 110. The material of the first substrate 110 or the second substrate 120 may include glass, quartz, or other suitable materials, or combinations of the above materials, but the disclosure is not limited thereto.

The first light-emitting element 112A and the second light-emitting element 114A are disposed on the first substrate 110 and located between the first substrate 110 and the second substrate 120. The first substrate 110 may be an active element substrate or other substrate that can be used to provide driving signals and/or power to sub-pixels, such as the first sub-pixel 112 and the second sub-pixel 114. A bottom surface 120B of the second substrate 120 and a top surface 110T of the first substrate 110 may have a height H along the third direction D3, with the height H falling within a range of 5 micrometers to 15 micrometers.

A pixel unit 100A further includes a blocking layer WB. The blocking layer WB is disposed between the first substrate 110 and the second substrate 120 and is located between the photoluminescent layer YL and the second substrate 120. The material of the blocking layer WB may include black photoresist, white photoresist, photoresist of other colors, or metal, but the disclosure is not limited thereto. In some embodiments, the material of the blocking layer WB may also include scattering particles. The material of the scattering particles may be, for example, titanium dioxide, but the disclosure is not limited thereto.

The pixel unit 100A further includes a plurality of shielding elements BM. The plurality of shielding elements BM may be disposed on the surface of the second substrate 120 facing the first substrate 110 and located between the blocking layer WB and the second substrate 120. The material of the plurality of shielding elements BM may include black resin, gray resin, white resin, titanium black, or carbon black, but the disclosure is not limited thereto.

FIG. 1C is a relationship diagram between horizontal viewing angle and relative intensity according to an embodiment of the disclosure. FIG. 1D is a relationship diagram between horizontal viewing angle and relative intensity according to an embodiment of the disclosure. FIG. 1E is a relationship diagram between horizontal viewing angle and relative intensity according to an embodiment of the disclosure. Please refer to FIG. 1C to FIG. 1E simultaneously. FIG. 1C shows a weight percent concentration of the diffusion particles YP in the photoluminescent layer YL at 0% range, FIG. 1D shows a weight percent concentration of the diffusion particles YP in the photoluminescent layer YL falling in the range of 1.5%, and FIG. 1E shows a weight percent concentration of the diffusion particles YP in the photoluminescent layer YL falling in the range of 3%. Comparing FIG. 1C, FIG. 1D, and FIG. 1E, it may be found that when the weight percent concentration of the diffusion particles YP in the photoluminescent layer YL gradually increases from 0% to 1.5% and finally to 3%, the display device clearly exhibits better light concentration effect. Therefore, gradually increasing the weight percent concentration of the diffusion particles YP in the photoluminescent layer YL can effectively enhance the light concentration effect of the display device and reduce color shift in the left/right viewing angle directions.

As described in FIG. 1A and FIG. 1B, the width of the shielding element BM along a first direction D1 is W1, and the length of the shielding element BM along a second direction D2 is L1. In the first direction D1, the opening width of the blocking layer WB of the first sub-pixel 112 is W2, the opening width of the blocking layer WB of the second sub-pixel 114 is W3, the opening width of the blocking layer WB of the third sub-pixel 116 is W4, and the opening width of the blocking layer WB of the fourth sub-pixel 118 is W5. In the second direction D2, the opening length of the blocking layer WB of the first sub-pixel 112 is L2, the opening length of the blocking layer WB of the second sub-pixel 114 is L3, the opening length of the blocking layer WB of the third sub-pixel 116 is L4, and the opening length of the blocking layer WB of the fourth sub-pixel 118 is L5. There is a spacing W6 between the first light-emitting element 112A and the second light-emitting element 114A, a spacing W7 between the second light-emitting element 114A and the third light-emitting element 116A, and a spacing W8 between the third light-emitting element 116A and the fourth light-emitting element 118A.

In this embodiment, when W1 and W6 to W8 increase simultaneously, the optical crosstalk between the first light-emitting element 112A and the second light-emitting element 114A, between the second light-emitting element 114A and the third light-emitting element 116A, or between the third light-emitting element 116A and the fourth light-emitting element 118A may be reduced accordingly. In some embodiments, when W1 and W2 to W8 increase simultaneously, the optical crosstalk between the first light-emitting element 112A and the second light-emitting element 114A, between the second light-emitting element 114A and the third light-emitting element 116A, or between the third light-emitting element 116A and the fourth light-emitting element 118A may also be reduced accordingly, but the disclosure is not limited thereto.

In some embodiments, when the weight percent concentration of the diffusion particles YP in the photoluminescent layer YL increases from 0.5% to 2%, and then to 3.5%, the optical crosstalk between the first light-emitting element 112A and the second light-emitting element 114A, between the second light-emitting element 114A and the third light-emitting element 116A, or between the third light-emitting element 116A and the fourth light-emitting element 118A may also be reduced accordingly.

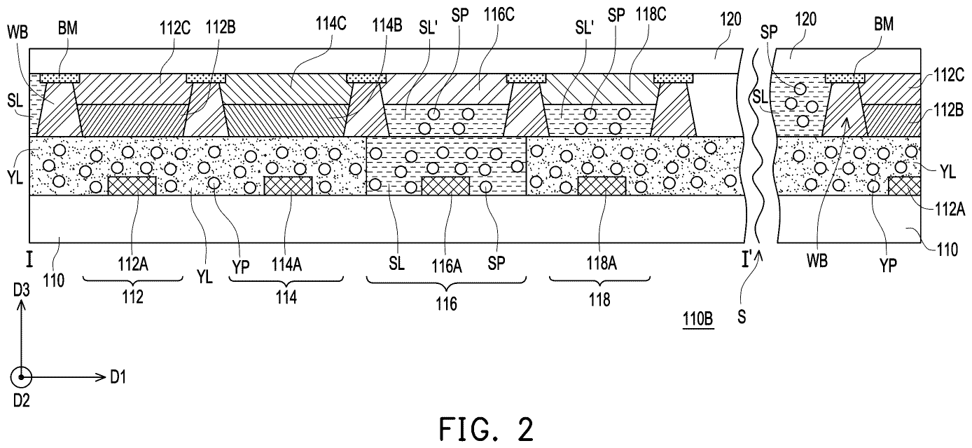

FIG. 2 is a cross-sectional schematic diagram of one of the pixel units and the seam S between the display panels according to another embodiment of the disclosure. A pixel unit 100B is similar to the pixel unit 100A, with the main difference being that a scattering layer SL is located on the third light-emitting element 116A and laterally covers the sidewall of the third light-emitting element 116A, a scattering layer SL′ is located on the scattering layer SL and between the third filter layer 116C and laterally covers part of the sidewall of the blocking layer WB, the scattering layer SL and the scattering layer SL′ include scattering particles SP, the scattering particles SP may be, for example, titanium dioxide particles, the third filter layer 116C is disposed on the scattering layer SL', and since the scattering layer SL is located on the third light-emitting element 116A and laterally covers the sidewall of the third light-emitting element 116A, and the scattering layer SL′ is located on the scattering layer SL and between the third filter layer 116C and laterally covers part of the sidewall of the blocking layer WB, the third light-emitting element 116A may avoid total internal reflection, providing the display device with better light concentration efficiency and reduced color shift in the left/right horizontal viewing angle directions.

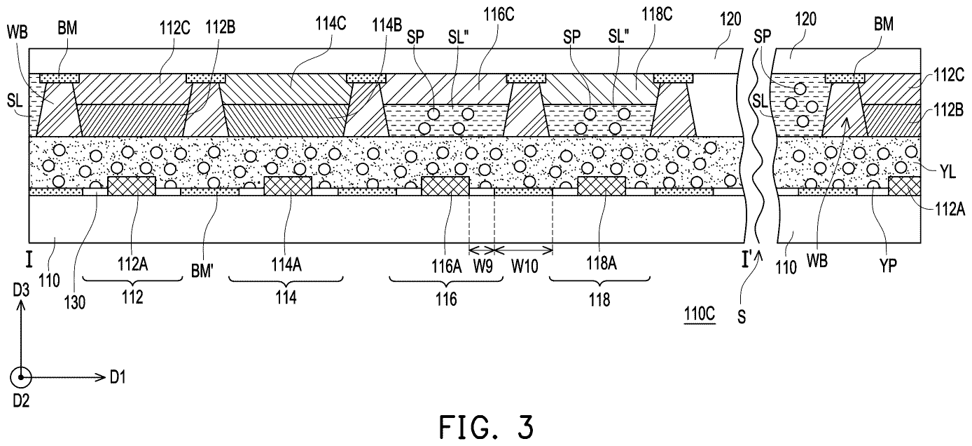

FIG. 3 is a cross-sectional schematic diagram of one of the pixel units and the seam S between the display panels according to another embodiment of the disclosure. A pixel unit 100C is similar to the pixel unit 100A, with the main difference being that a scattering layer SL″ is located between the third filter layer 116C and the still another portion of the photoluminescent layer YL and laterally covers part of the sidewall of the blocking layer WB, a shielding element BM′ may be located between the first light-emitting element 112A and the second light-emitting element 114A, and between the second light-emitting element 114A and the third light-emitting element 116A, and between the third light-emitting element 116A and the fourth light-emitting element 118A and has a width W10, a reflective layer 130 may be located between the first light-emitting element 112A and the shielding element BM′, and between the second light-emitting element 114A and the shielding element BM′, and between the third light-emitting element 116A and the shielding element BM′, and between the fourth light-emitting element 118A and the shielding element BM′ and has a width W9, the width W10 is greater than or equal to the width W9, and since the width W10 of the shielding element BM′ is greater than or equal to the width W9 of the reflective layer 130, the optical crosstalk between sub-pixels may thus be reduced, and the display device may therefore enhance the light emission efficiency.

In some embodiments, the ratio of the width W10 of the shielding element BM′ to the width W9 of the reflective layer 130 falls within the range of 1 to 2.5.

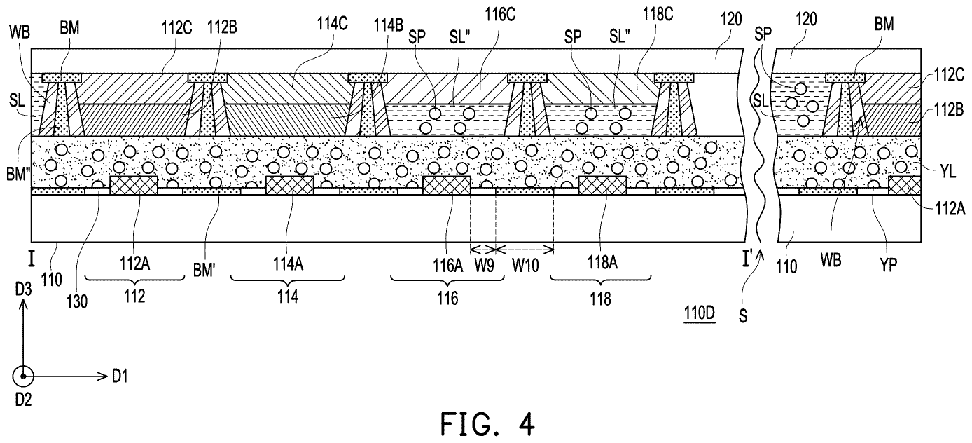

FIG. 4 is a cross-sectional schematic diagram of one of the pixel units and the seam S between the display panels according to another embodiment of the disclosure. A pixel unit 100D is similar to the pixel unit 100C, with the main difference being that the pixel unit 100D further includes a shielding element BM″ disposed within the blocking layer WB, the shielding element BM is disposed on a side of the second substrate 120 facing the first substrate 110, the shielding element BM″ is overlapped with the shielding element BM, the blocking layer WB laterally covers the shielding element BM″, and the transmittance of the shielding element BM toward visible light is lower than the transmittance of the blocking layer WB toward visible light, since the transmittance of the shielding element BM toward visible light is lower than the transmittance of the blocking layer WB toward visible light, the shielding element BM″ may suppress visible light transmission, the optical crosstalk between sub-pixels may thus be reduced, and the display device may therefore enhance the light emission efficiency. In some embodiments, the shielding element BM″ may also laterally cover the blocking layer WB, but the disclosure is not limited thereto.

In summary, in the display device of the disclosure, a portion of the photoluminescent layer is located between the first light-emitting element and the first filter layer and laterally covers the sidewall of the first light-emitting element, another portion of the photoluminescent layer is located between the second light-emitting element and the second filter layer and laterally covers the sidewall of the second light-emitting element, and the first sub-pixel and the second sub-pixel are configured to emit light of different colors. As such, the display device has better light concentration efficiency and energy-saving efficiency, as well as reduced color shift in the left/right viewing angle directions.

What is claimed is:

1. A display device, comprising:
a photoluminescent layer; and
a pixel unit, comprising:
a first sub-pixel, comprising:
a first light-emitting element; and
a first filter layer disposed above the first light-emitting element, wherein a portion of the photoluminescent layer is located between the first light-emitting element and the first filter layer, and the photoluminescent layer laterally covers a sidewall of the first light-emitting element; and
a second sub-pixel, comprising:
a second light-emitting element; and
a second filter layer disposed above the second light-emitting element, wherein another portion of the photoluminescent layer is located between the second light-emitting element and the second filter layer, and the photoluminescent layer laterally covers a sidewall of the second light-emitting element,
wherein the first sub-pixel and the second sub-pixel are configured to emit light of different colors.

2. The display device as claimed in claim 1, wherein the first sub-pixel further comprises a first color conversion structure, the second sub-pixel further comprises a second color conversion structure, the first color conversion structure is disposed above the first light-emitting element, the portion of the photoluminescent layer is located between the first color conversion structure and the first light-emitting element, the second color conversion structure is disposed above the second light-emitting element, and the another portion of the photoluminescent layer is located between the second color conversion structure and the second light-emitting element.

3. The display device as claimed in claim 2, wherein the photoluminescent layer comprises photoluminescent particles and diffusion particles, a size of the photoluminescent particles falls within a range of 0.1 micrometers to 5 micrometers, a size of the diffusion particles falls within a range of 0.1 micrometers to 1 micrometer, a weight percent concentration of the photoluminescent particles in the photoluminescent layer falls within a range of 40% to 60%, and a weight percent concentration of the diffusion particles in the photoluminescent layer falls within a range of 0.5% to 20%.

4. The display device as claimed in claim 1, wherein the pixel unit further comprises:
a third sub-pixel, comprising:
a third light-emitting element; and
a third filter layer disposed above the third light-emitting element, wherein still another portion of the photoluminescent layer is located between the third light-emitting element and the third filter layer, and the photoluminescent layer laterally covers a sidewall of the third light-emitting element; and
a fourth sub-pixel, comprising:
a fourth light-emitting element; and
a fourth filter layer disposed above the fourth light-emitting element, wherein yet another portion of the photoluminescent layer is located between the fourth light-emitting element and the fourth filter layer, and the photoluminescent layer laterally covers a sidewall of the fourth light-emitting element, wherein the first sub-pixel, the second sub-pixel, the third sub-pixel, and the fourth sub-pixel are configured to emit light of different colors.

5. The display device as claimed in claim 1, further comprising:
a shielding element located between the first light-emitting element and the second light-emitting element, wherein the shielding element has a first width between the first light-emitting element and the second light-emitting element; and
a reflective layer located between the first light-emitting element and the shielding element and between the second light-emitting element and the shielding element, wherein a width of the reflective layer between the first light-emitting element and the shielding element and a width of the reflective layer between the second light-emitting element and the shielding element are each a second width, and the first width is greater than or equal to the second width.

6. The display device as claimed in claim 5, wherein a ratio of the second width to the first width falls within a range of 1 to 2.5.

7. The display device as claimed in claim 1, further comprising:
a first substrate, wherein the first light-emitting element and the second light-emitting element are disposed on the first substrate; and
a second substrate overlapped with the first substrate, wherein the first filter layer and the second filter layer are disposed on the second substrate, the first light-emitting element, the second light-emitting element, the first filter layer, the second filter layer, and the photoluminescent layer are located between the first substrate and the second substrate, and the photoluminescent layer is located between the second substrate and the first light-emitting element and between the second substrate and the second light-emitting element.

8. The display device as claimed in claim 7, wherein the pixel unit further comprises:
a blocking layer disposed between the photoluminescent layer and the second substrate;
a first shielding element disposed on a side of the second substrate facing the first substrate; and
a second shielding element overlapped with the first shielding element, wherein the blocking layer laterally covers the second shielding element, and a transmittance of the first shielding element toward visible light is lower than a transmittance of the blocking layer toward visible light.

9. The display device as claimed in claim 8, wherein a material of the blocking layer comprises titanium dioxide.

10. The display device as claimed in claim 8, wherein a material of the first shielding element and the second shielding element comprises titanium black or carbon black.

11. A display device, comprising:
a photoluminescent layer; and
a pixel unit, comprising:
a first sub-pixel, comprising:
a first light-emitting element; and
a first color conversion structure, wherein the first color conversion structure is disposed above the first light-emitting element, and the portion of the photoluminescent layer is located between the first color conversion structure and the first light-emitting element; and
a second sub-pixel, comprising:
a second light-emitting element; and
a second color conversion structure, wherein the second color conversion structure is disposed above the second light-emitting element, and the another portion of the photoluminescent layer is located between the second color conversion structure and the second light-emitting element,
wherein the first sub-pixel and the second sub-pixel are configured to emit light of different colors.

12. The display device as claimed in claim 11, wherein the photoluminescent layer comprises photoluminescent particles and diffusion particles, a size of the photoluminescent particles falls within a range of 0.1 micrometer to 5 micrometers, a size of the diffusion particles falls within a range of 0.1 micrometer to 1 micrometer, a weight percent concentration of the photoluminescent particles in the photoluminescent layer falls within a range of 40% to 60%, and a weight percent concentration of the diffusion particles in the photoluminescent layer falls within a range of 0.5% to 20%.

13. The display device as claimed in claim 12, wherein the pixel unit further comprises:
a third sub-pixel comprising:
a third light-emitting element; and
a third filter layer disposed above the third light-emitting element, wherein still another portion of the photoluminescent layer is located between the third light-emitting element and the third filter layer, and the photoluminescent layer laterally covers a sidewall of the third light-emitting element; and
a fourth sub-pixel, comprising:
a fourth light-emitting element; and
a fourth filter layer disposed above the fourth light-emitting element, wherein yet another portion of the photoluminescent layer is located between the fourth light-emitting element and the fourth filter layer, and the photoluminescent layer laterally covers a sidewall of the fourth light-emitting element, wherein the first sub-pixel, the second sub-pixel, the third sub-pixel, and the fourth sub-pixel are configured to emit light of different colors.

14. The display device as claimed in claim 11, further comprising:
a shielding element located between the first light-emitting element and the second light-emitting element, wherein the shielding element has a first width between the first light-emitting element and the second light-emitting element; and
a reflective layer located between the first light-emitting element and the shielding element and between the second light-emitting element and the shielding element, wherein a width of the reflective layer between the first light-emitting element and the shielding element and a width of the reflective layer between the second light-emitting element and the shielding element are each a second width, and the first width is greater than or equal to the second width.

15. The display device as claimed in claim 14, wherein a ratio of the second width to the first width falls within a range of 1 to 2.5.

16. The display device as claimed in claim 11, further comprising:
a first substrate, wherein the first light-emitting element and the second light-emitting element are disposed on the first substrate; and
a second substrate overlapped with the first substrate, wherein the first filter layer and the second filter layer are disposed on the second substrate, the first light-emitting element, the second light-emitting element, the first filter layer, the second filter layer, and the photoluminescent layer are located between the first substrate and the second substrate, and the photoluminescent layer is located between the second substrate and the first light-emitting element and between the second substrate and the second light-emitting element.

17. The display device as claimed in claim 11, wherein the first sub-pixel comprises a first filter layer disposed above the first light-emitting element, a portion of the photoluminescent layer is located between the first light-emitting element and the first filter layer, and the photoluminescent layer laterally covers a sidewall of the first light-emitting element.

18. The display device as claimed in claim 11, wherein the second sub-pixel comprises a second filter layer disposed above the second light-emitting element, another portion of the photoluminescent layer is located between the second light-emitting element and the second filter layer, and the photoluminescent layer laterally covers a sidewall of the second light-emitting element.

19. The display device as claimed in claim 16, wherein the pixel unit further comprises:
a blocking layer disposed between the photoluminescent layer and the second substrate;
a first shielding element disposed on a side of the second substrate facing the first substrate; and
a second shielding element overlapped with the first shielding element, wherein the blocking layer laterally covers the second shielding element, and a transmittance of the first shielding element toward visible light is lower than a transmittance of the blocking layer toward visible light.

20. The display device as claimed in claim 19, wherein a material of the blocking layer comprises titanium dioxide.
